(19) United States
(12) Patent Application Publication
(10) Pub. No.: US 2017/0358538 A1
(43) Pub. Date: Dec. 14, 2017

(54) SEMICONDUCTOR DEVICE AND METHOD FOR MANUFACTURING THE SAME

(71) Applicant: Renesas Electronics Corporation, Tokyo (JP)

(72) Inventor: Kazuhisa SAWADA, Ibaraki (JP)

(21) Appl. No.: 15/481,357

(22) Filed: Apr. 6, 2017

(30) Foreign Application Priority Data
Jun. 8, 2016 (JP) 2016-114504

(51) Int. Cl. H01L 23/544

(52) U.S. Cl. CPC H01L 23/544; H01L 2223/54406

(57) ABSTRACT

A marking structure where marking visibility is improved is provided. In a semiconductor device having a marking structure, the marking structure includes: a body for marking having a surface; a first mark group having a first concave portion formed in the surface; a second mark group having a second concave portion formed adjacent to the first concave portion in the surface. The first concave portion and the second concave portion differ in shape so that they may cause light reflection differently. Thus, visibility of the marking structure can be improved.

### CROSS-REFERENCE TO RELATED APPLICATIONS

The disclosure of Japanese Patent Application No. 2016-114504 filed on Jun. 8, 2016 including the specification, drawings and abstract is incorporated herein by reference in its entirety.

### BACKGROUND

The present invention relates to a semiconductor device and a method for manufacturing the same.

Japanese Unexamined Patent Application Publication No. 2014-154661 (Patent Document 1) discloses a marking structure where a plurality of dots are formed in a surface of a semiconductor wafer etc. In the marking structure described in Patent Document 1, visibility of the marking structure is improved by optimizing a depth of each dot.

[Patent Document]
[Patent Document 1] Japanese Unexamined Patent Application Publication No. 2014-154661

### SUMMARY

According to the marking structure described in Patent Document 1, the shape of each dot is uniform. Therefore, when a depth of the dot is too shallow, marking will fade. On the other hand, when the depth of the dot is too deep, marking bodies such as a semiconductor wafer etc. will scatter, generating particles.

Other objects and novel features will be apparent from the following description taken in conjunction with the accompanying drawings.

A semiconductor device according to one embodiment has a marking structure. The marking structure includes a body for marking having a surface, a first mark group having a first concave portion formed in the surface, and a second mark group having a second concave portion formed adjacent to the first concave portion in the surface. The first concave portion and the second concave portion differ in shape so that they may cause light reflection differently.

According to the semiconductor device of one embodiment, it becomes possible to improve visibility of the marking structure.

### BRIEF DESCRIPTION OF THE DRAWINGS

FIGS. 1A and 1B are top views of marking structure according to Embodiment 1;

FIG. 2 is a cross-sectional view of the marking structure according to Embodiment 1;

FIG. 3 is a process flowchart in a marking method according to Embodiment 1;

FIG. 4 is a cross-sectional view of the marking structure in a first concave portion forming step;

FIG. 5 is a cross-sectional view of the marking structure in a second concave portion forming step;

FIG. 6 is a cross-sectional view of the marking structure according a comparative example;

FIGS. 7A and 7B are schematic diagrams showing a state of reflection when light is applied to the marking structure according to Embodiment 1 and the marking structure according to the comparative example;

FIG. 8 is a cross-sectional view of the marking structure according to Embodiment 2;

FIG. 9 is a process flowchart in a marking method according to Embodiment 2;

FIG. 10 is a cross-sectional view of the marking structure in a concave portion forming step;

FIGS. 11A and 11B are cross-sectional views of the marking structure in a surface roughening step;

FIG. 12 is a schematic diagram showing a state of reflection when light is applied to the marking structure according to Embodiment 2;

FIGS. 13A and 13B are cross-sectional views of the marking structure according to Embodiment 3;

FIG. 14 is a top view of the marking structure according to Embodiment 3;

FIGS. 15A and 15B are cross-sectional views of the marking structure in the first concave portion forming step;

FIGS. 16A and 16B are cross-sectional views of the marking structure in the second concave portion forming step;

FIG. 17 is a schematic diagram showing a state of reflection when light is applied to the marking structure according to Embodiment 3; and

FIGS. 18A and 18B are cross-sectional views of the marking structure according to Embodiment 4.

### DETAILED DESCRIPTION

Hereinafter, embodiments will be explained with reference to drawings. Further, like reference characters designate the same or similar parts throughout the drawings. Also, at least some parts of the embodiments described below may be combined as required.

### Embodiment 1

Now, the configuration of a semiconductor device according to Embodiment 1 will be explained. Further, in the semiconductor device, a wafer in which semiconductor elements, such as a transistor, are formed shall also be included.

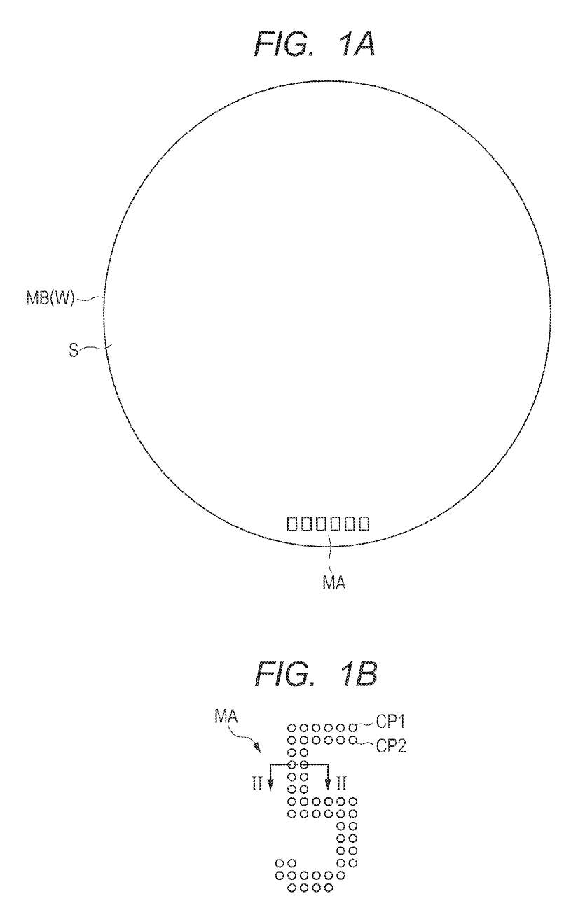

As shown in FIG. 1A, the semiconductor device according to Embodiment 1 has a marking structure MA. The marking structure MA includes a body for marking MB. The body for marking MB is a semiconductor wafer W in the semiconductor device according to Embodiment 1. The semiconductor wafer W has a surface S.

As shown in FIG. 1B, the marking structure MA has a first mark group including a first concave portion CP1 and a second mark group including a second concave portion CP2. The first concave portion CP1 is formed over the surface S of the semiconductor wafer W. The second concave portion CP2 is formed over the surface S of the semiconductor wafer W. The first concave portion CP1 and the second concave portion CP2 are formed being adjacent to each other. Further, the first concave portion CP1 and the second concave portion CP2 should just be adjacent to each other at least in one direction.

The first concave portion CP1 and the second concave portion CP2 are so arranged as to draw characters such as an alphabet, a numeric, etc. For example, in FIG. 1B, a numeric 5 is drawn by the first concave portion CP1 and the second concave portion CP2. In this way, the first concave portion CP1 and the second concave portion CP2 show information. The information is, for example, a lot number of the semiconductor wafer W, a wafer number of the semiconductor wafer W, etc.

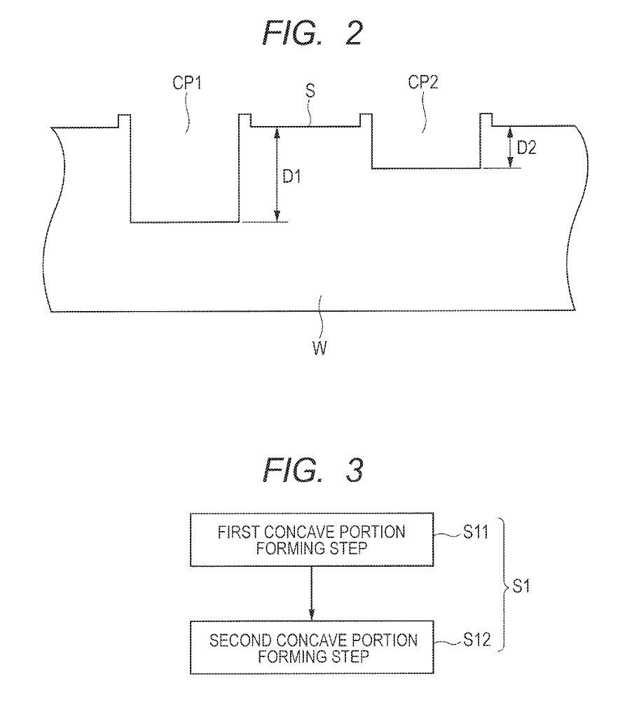

As shown in FIG. 2, the first concave portion CP1 and the second concave portion CP differ in shape so that they may cause light reflection differently. More specifically, the first concave portion CP1 has a first depth D1. The first depth D1 is a distance from the surface S of the semiconductor wafer W to a bottom of the first concave portion CP1. The second concave portion CP2 has a second depth D2. The second depth D2 is a distance from the surface S of the semiconductor wafer W to a bottom of the second concave portion CP2. The first depth D1 is different from the second depth D2. For example, the first depth D1 is deeper than the second depth D2. As a result, the first concave portion CP1 and the second concave portion CP2 are different in shape.

Hereafter, a method for manufacturing a semiconductor device according to Embodiment 1 will be explained. As shown in FIG. 3, the method for manufacturing a semiconductor device according to Embodiment 1 includes a concave portion forming step S1. The concave portion forming step S1 includes a first concave portion forming step Sll and a second concave portion forming step S12. The first concave portion CP 1 is formed in the first concave portion forming step S11. The concave portion CP2 is formed in the second concave portion forming step S12.

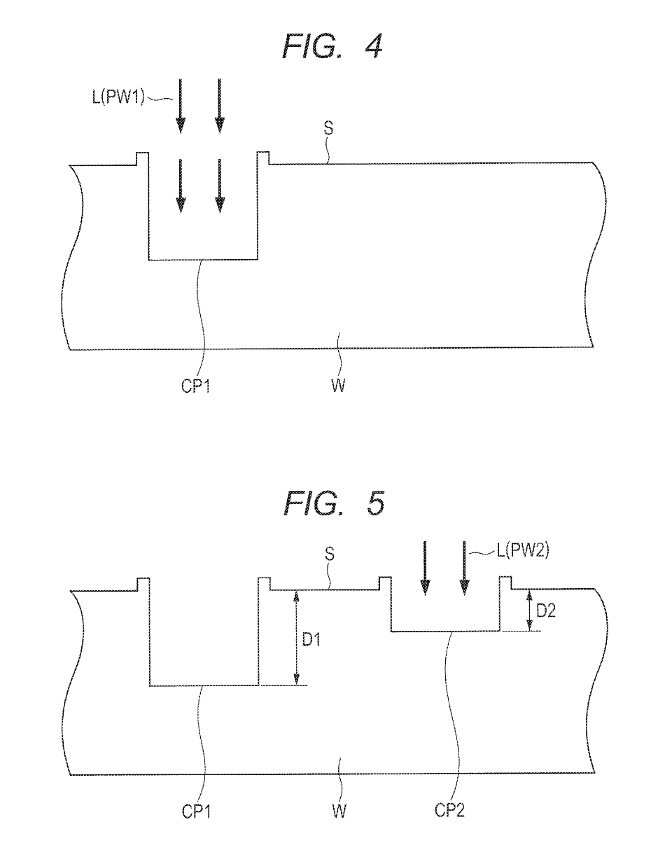

As shown in FIG. 4, in the first concave portion forming step S11, laser L is applied to the surface S of the semiconductor wafer W. As a result, the first concave portion CP1 is formed. The laser L is, for example, a YAG (Yttrium Aluminum Garnet) laser. In the first concave portion forming step S11, the laser L is applied to the surface S of the semiconductor wafer W with a first intensity PW1. In the first concave portion forming step S11, by allowing the laser L to scan, the first concave portions CP1 are formed.

As shown in FIG. 5, in the second concave portion formation step S12, laser L is applied to the surface S of the semiconductor wafer W. As a result, the second concave portion CP2 is formed. In the second concave portion formation step S12, the laser L is applied to the surface S of the semiconductor wafer W with a second intensity PW2 at a position adjacent to where the first concave portion CP1 is formed. Thus, the second concave portion CP2 and the first concave portion CP1 are formed being adjacent to each other. In the second concave portion forming step S12, by allowing the laser L to scan, the second concave portions CP2 are formed.

The second intensity PW2 differs from the first intensity PW1. For example, the second intensity PW2 is smaller than the first intensity PW1. Therefore, the second depth D2 of the second concave portion CP2 becomes shallower than the first depth D1 of the first concave portion CP1. Thus, by changing the intensity of the laser L, it becomes possible to allow the second depth D2 of the second concave portion cP2 to be different from the first depth D1 of the first concave portion CP1.

Hereinafter, in comparison with a comparative example, effects of the semiconductor device according to Embodiment 1 will be explained.

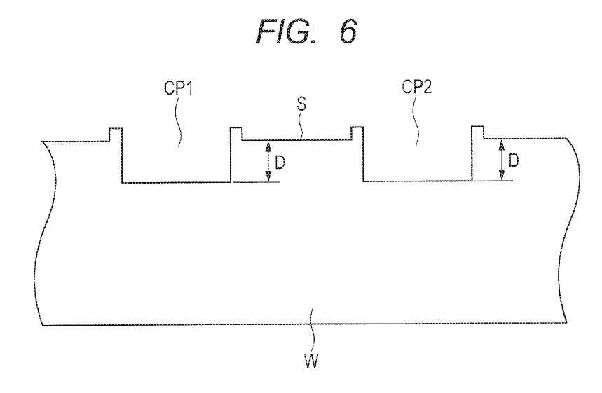

As shown in FIG. 6, a marking structure MA according to the comparative example has a semiconductor wafer W, a first concave portion CP1, and a second concave portion CP2. The semiconductor wafer W has a surface S. The first concave portion CP1 and the second concave portion CP2 are formed in the surface S of the semiconductor wafer W. The first concave portion CP1 and the second concave portion CP2 are arranged being adjacent to each other. In those respects, the marking structure of the semiconductor device according to Embodiment 1 and the marking structure according to the comparative example are the same.

However, the first concave portion CP1 and the second concave portion CP2 have the same shape. More specifically, the first concave portion CP1 and the second concave portion CP2 have the same depth D. In this respect, the marking structure of the semiconductor device according to Embodiment 1 and the marking structure according to the comparative example are different.

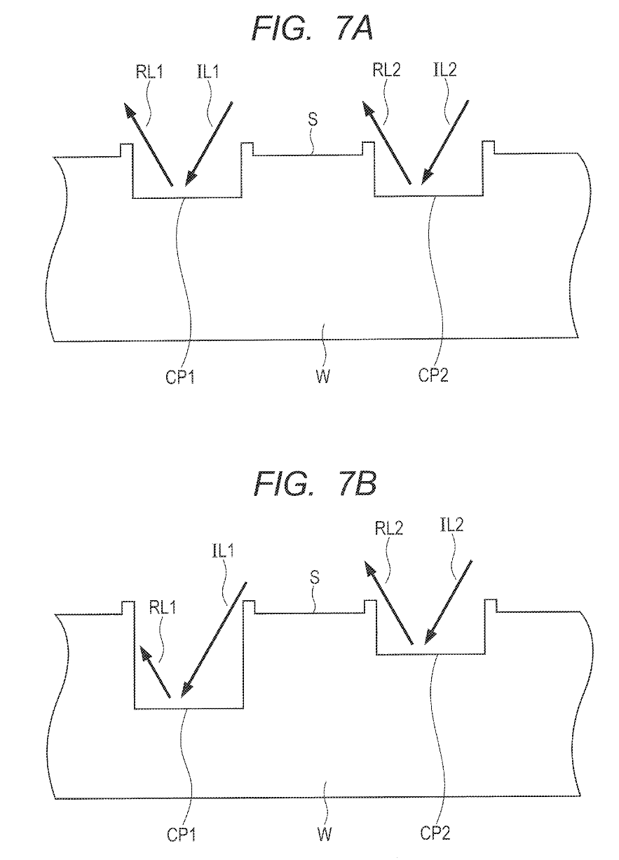

As shown in FIG. 7A, in the marking structure according to the comparative example, incident light IL1 and incident light IL2 are reflected in the first concave portion CP1 and the second concave portion CP2, respectively. As described above, the first concave portion CP1 and the second concave portion CP2 have the same shape (the same depth). Consequently, there occurs no variation in intensity between the reflected light RL1 from the first concave portion CP1 and the reflected light RL2 from the second concave portion CP2. That is, a contract is less likely to be presented between the reflected light RL1 from the first concave portion CP1 and the reflected light RL2 from the second concave portion CP2. As a result, in the marking structure according to the comparative example, visibility of the marking is low.

As shown in FIG. 7B, also in the marking structure MA of the semiconductor device according Embodiment 1, incident light IL1 and incident light IL2 are reflected in the first concave portion CP1 and the second concave portion CP2, respectively. As described above, the first concave portion CP1 and the second concave portion CP2 are different in shape (different in depth). Therefore, for example, because of reflected light RL2 from the second concave portion CP2 being interrupted by a side part etc. of the second concave portion CP2, intensity of the reflected light RL and intensity of the reflected light RL2 come to be different. That is, a contrast is presented between the reflected light RL1 from the first concave portion CP1 and the reflected light RL2 from the second concave portion CP2.

Therefore, according to the marking structure of the semiconductor device of Embodiment 1, visibility of the marking can be improved.

Hereafter, effects of a method for manufacturing a semiconductor device according to Embodiment 1 will be explained. According to the method for manufacturing a semiconductor device of Embodiment 1, the visibility of the marking can be secured even when the first concave portion CP1 and the second concave portion CP2 are not deeply formed.

Therefore, in the method for manufacturing a semiconductor device according to Embodiment 1, when the first concave portion CP1 and the second concave portion CP2 are formed with use of laser L, it becomes possible to suppress generation of particles in the marking process.

Moreover, in the method for manufacturing a semiconductor device according to Embodiment 1, when the first concave portion CP1 is formed by applying laser L with a first intensity PW1 and the second concave portion CP2 is formed by applying laser L with a second intensity PW2 which is different from the first intensity PW1, it becomes possible to obtain, with ease, the marking structure whose visibility is improved.

### Embodiment 2

Hereinafter, the configuration of a semiconductor device according to Embodiment 2 will be explained. In this regard, points which are different from those of Embodiment 1 will be mainly explained.

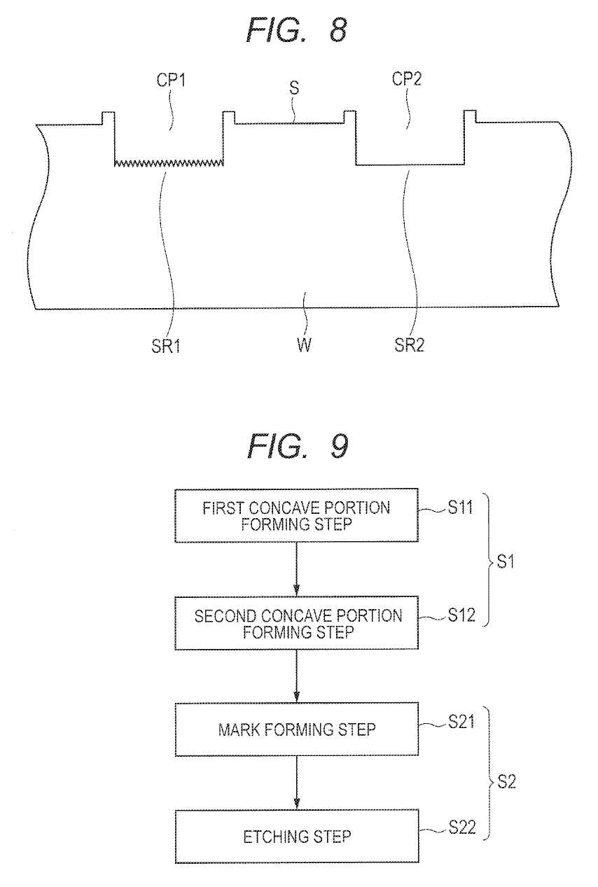

As shown in FIG. 8, like the marking structure MA of Embodiment 1, a marking structure MA of the semiconductor device according to Embodiment 2 has a semiconductor wafer W as a body for marking MB, a first mark group including a first concave portion CP1, and a second mark group including a second concave portion CP2. As in the marking structure MA according to Embodiment 1, in the marking structure MA of the semiconductor device according to Embodiment 2, the first concave portion CP1 and the second concave portion CP2 are different in shape.

According to Embodiment 2, a bottom of the first concave portion CP1 has a first surface roughness SR1. The first surface roughness SR1 is an average surface roughness at the bottom of the first concave portion CP1. Also, a bottom of the second concave portion CP2 has a second surface roughness SR2. The surface roughness SR2 is an average surface roughness at the bottom of the second concave portion CP2. In addition, the average surface roughness is measured in accordance with a method specified in a contact type roughness measuring or a non-contact type roughness measuring. The first surface roughness SR1 is greater than the second surface roughness SR2.

That is, the first concave portion CP 1 is so configured as to scatter incident light more than the second concave portion CP2.

Hereafter, a method for manufacturing a semiconductor device according to Embodiment 2 will be explained. As shown in FIG. 9, the method for manufacturing a semiconductor device according to Embodiment 2 includes a concave portion forming step S1 and a surface roughening step S2. The concave portion forming step S1 has a first concave portion forming step S11 and a second concave portion forming step S12.

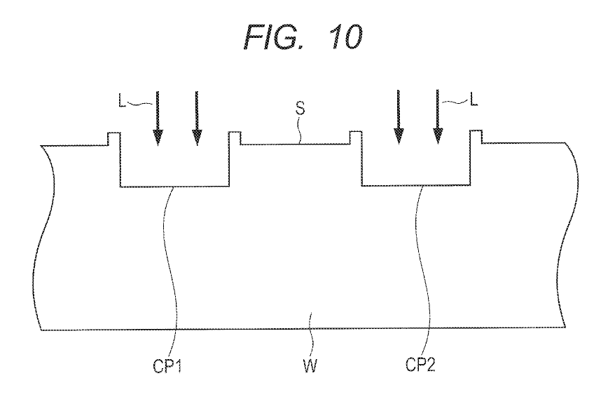

As shown in FIG. 10, in the first concave portion forming step S11, the first concave portion CP1 is formed, for example, by using laser L. In the second concave portion forming step S12, the second concave portion CP2 is formed, for example, by using laser L. In addition, a first intensity PW1 of the laser L and a second intensity PW2 of the laser L may be the same or may be different.

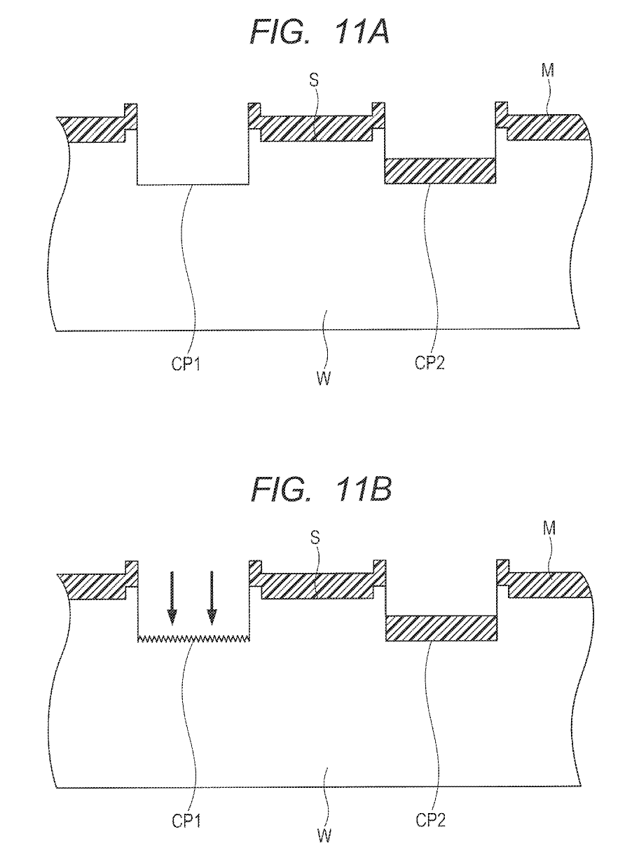

The surface roughening step S2 includes a mask forming step S21 and an etching step S22. In the mask forming step S21, as shown in FIG. 11A, a mask M is formed over the surface S of the semiconductor wafer W and a bottom of the second concave portion CP2. In other words, the mask M is not formed over the bottom of the first concave portion CP1.

The mask M includes, for example, a photosensitive organic material, such as a photo-resist. The mask M is formed, for example, by applying a photo-resist etc. over the surface S of the semiconductor wafer W and, then, by performing patterning through photolithography etc.

In the etching step S22, as shown in FIG. 11B, etching is applied to the bottom of the first concave portion CP1. Since the mask M is formed over the bottom of the second concave portion CP2 as described above, the etching is not applied to the bottom of the second concave portion CP2. Therefore, as a result of the etching step S22, a first surface roughness SR 1 becomes greater than a second surface roughness SR2. In addition, the above etching is performed either by wet etching or by dry etching.

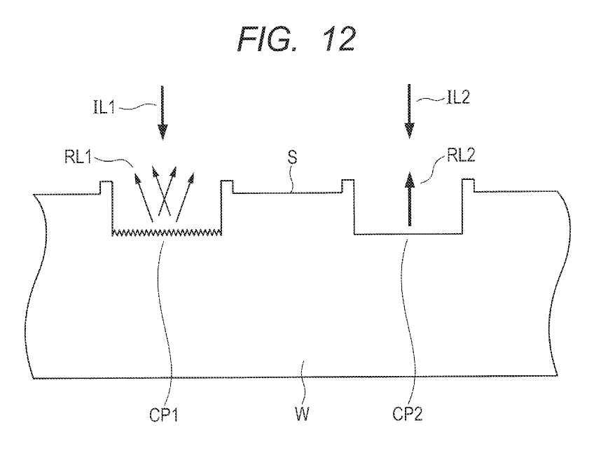

Hereinafter, effects of the marking structure of the semiconductor device according to Embodiment 2 will be explained. The first surface roughness SR1 is greater than the second surface roughness SR2. Therefore, as shown in FIG. 12, incident light IL1 having entered the first concave portion CP1 is scattered in the bottom of the first concave portion CP1. As a result, the intensity of reflected light RL1 from the first concave portion CP1 becomes weakened.

On the other hand, the second surface roughness SR2 is smaller than the first surface roughness SR1. Therefore, incident light IL2 having entered the second concave portion CP2 is reflected normally, without being scattered. As a result, the intensity of reflected light RL2 from the second concave portion CP2 does not become weakened.

Consequently, there is presented a contrast of light and darkness between the first concave portion CP1 and the second concave portion CP2. Therefore, according to the marking structure of the semiconductor device of Embodiment 2, the visibility can be improved.

Hereinafter, effects of the method for manufacturing the semiconductor device according to Embodiment 2 will be explained. According to the marking method of Embodiment 2, it becomes possible to obtain the marking structure according to Embodiment 2. Therefore, according to the marking method of Embodiment 2, it becomes possible to provide the marking structure which improves the visibility.

### Embodiment 3

Hereinafter, the configuration of a marking structure of a semiconductor device according to Embodiment 3 will be explained. In this regard, the points which are different from those in Embodiment 1 will be mainly explained.

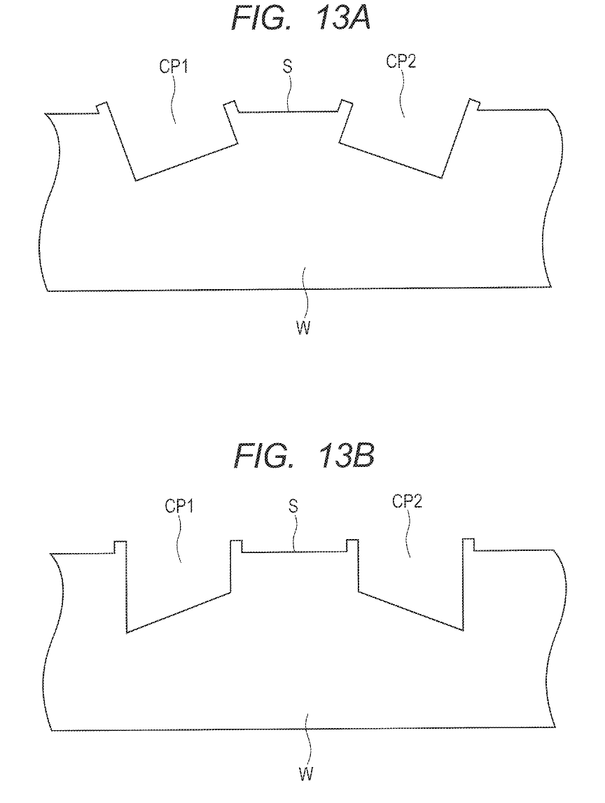

As shown in FIG. 13A, like the marking structure of the semiconductor device according to Embodiment 1, the marking structure of the semiconductor device according to Embodiment 3 includes a semiconductor wafer W as a body for marking, a first concave portion CP1, and a second concave portion CP2. Also, as in the marking structure of the semiconductor device according to Embodiment 1, in the marking structure of the semiconductor device according to Embodiment 2, the first concave portion CP1 and the second concave portion CP2 are different in shape.

Specifically, an angle which a side part of the first concave portion CP1 forms with respect to the surface S of the semiconductor wafer W differs from an angle which a side part of the second concave portion CP2 forms with respect to the surface S of the semiconductor wafer W. Moreover, an angle which a bottom of the first concave portion CP1 forms with respect to the surface S of the semiconductor wafer W differs from an angle which a bottom of the second concave portion CP2 forms with respect to the surface S of the semiconductor wafer W.

In addition, as shown in FIG. 13B, the angle which the side part of first concave portion CP1 forms with respect to the surface S of the semiconductor wafer W may be the same as the angle which the side part of the second concave portion CP2 forms with respect to the surface S of the semiconductor wafer W. In short, the first concave portion CP1 should just be configured as to reflect incident light in a direction different from one in which the second concave portion CP2 does.

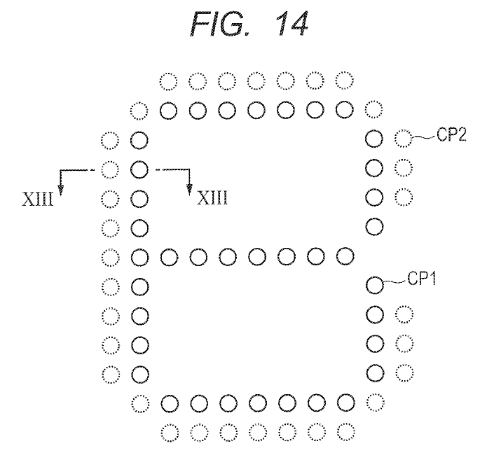

As shown in FIG. 14, over the surface S of the semiconductor wafer W, the plural first concave portions CP1 are formed. The first concave portions CP1 are so arranged as to express an alphabet, a numeric, etc. (in FIG. 14, they are so arranged as to express an alphabet B). Further, over the surface S of the semiconductor wafer W, the plural second concave portions CP2 are formed. The second concave portions CP2 are so arranged as to express an alphabet, a numeric, etc. (in FIG. 14, they are so arranged as to express an alphabet C).

The alphabet, the numeric, etc. expressed by the first concave portions CP1 are part of first text information. The alphabet, the numeric, etc. expressed by the second concave portions CP2 are part of second text information. The first text information and the second text information are different from each other. For example, when the first text information is a lot number of the semiconductor wafer W, the second text information is a wafer number of the semiconductor wafer W.

Hereafter, a method for manufacturing a semiconductor device according to Embodiment 3 will be explained. Like the method for manufacturing a semiconductor device according to Embodiment 1, the method for manufacturing a semiconductor device according to Embodiment 3 includes a concave portion forming step S1. Also, as in the marking method according to Embodiment 1, the concave portion forming step S1 includes a first concave portion forming step S11 and a second concave portion forming step S12.

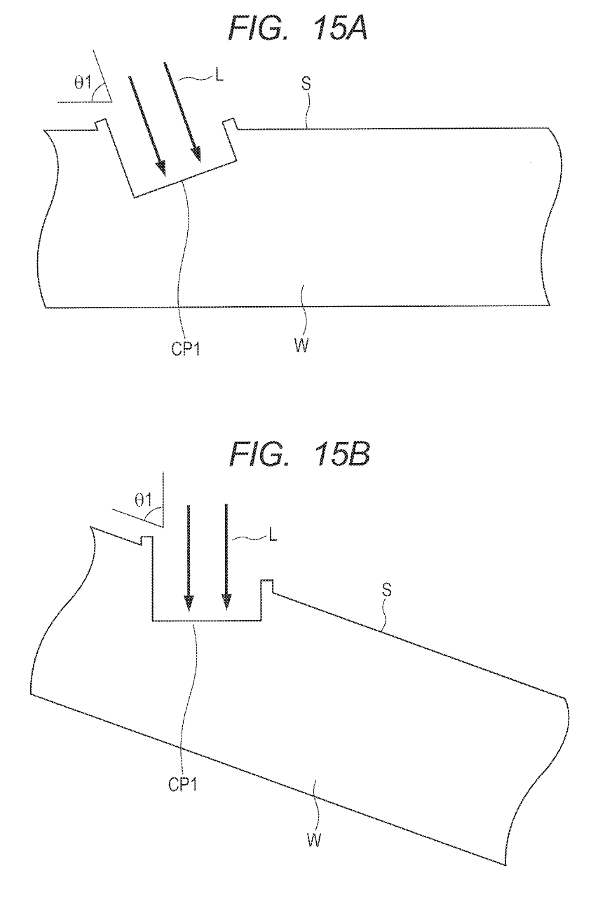

As shown in FIGS. 15A and 15B, in the first concave portion forming step S11, laser L is applied to the surface S of the semiconductor wafer W. The laser L is applied in an inclined manner at a first angle θ1 with respect to the surface S of the semiconductor wafer W. Accordingly, the first concave portion CP1 is formed. In the first concave portion forming step S11, by scanning the laser L, the plural first concave portions CP1 are formed.

Further, as shown in FIG. 15A, by providing an irradiation port of the laser L in an inclined manner with respect to the surface S of the semiconductor wafer W, the laser may be applied in an inclined manner at the first angle θ1 with respect to the surface S of the semiconductor wafer W. Alternatively, as shown in FIG. 15B, by providing the surface S of the semiconductor wafer W in an inclined manner with respect to the laser L, the laser L may be applied in an inclined manner at the first angle θ1 with respect to the surface S of the semiconductor wafer W.

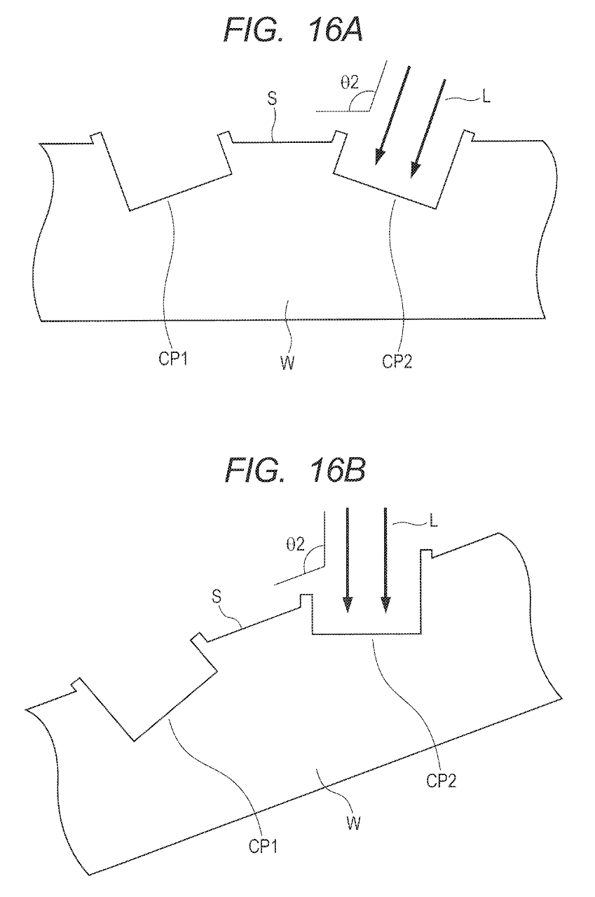

As shown in FIGS. 16A and 16B, in the second concave portion forming step S12, laser L is applied to the surface S of the semiconductor wafer W. The laser is applied in an inclined manner at a second angle θ2 with respect to the surface S of the semiconductor wafer W. The second angle θ2 is different from the first angle θ1. Thus, the second concave portion CP2 is formed. In the second concave portion forming step S12, by allowing the laser L to scan, the plural second concave portions CP2 are formed.

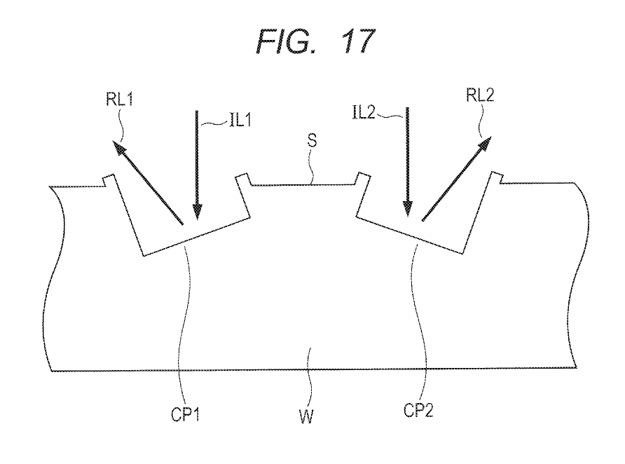

Hereinafter, effects of the semiconductor device according to Embodiment 3 will be explained. In the semiconductor device according to Embodiment 2, an angle which a bottom of the first concave portion CP1 forms with respect to the surface S of the semiconductor wafer W is different from an angle which a bottom of the second concave portion CP2 forms with respect to the surface S of the semiconductor wafer W. Therefore, as shown in FIG. 17, the incident light IL1 entering the first concave portion cP1 and the incident light IL2 entering the second concave portion cP2 are reflected in different directions. As a result, a contrast of light and darkness is presented between the first concave portion CP1 and the second concave portion CP2. Therefore, according to the semiconductor device of Embodiment 3, visibility of the marking can be improved.

To put it differently, the first concave portion CP1 alone is visible from one angle and the second concave portion CP2 alone is visible from another angle. Therefore, it becomes possible for the first concave portion CP1 to display first text information and for the second concave portion CP2 to display second text information being different from the first text information. As a result, it becomes possible to mark a lot of information in a small marking area.

Hereinafter, effects of a method for manufacturing a semiconductor device according to Embodiment 3 will be explained. According to a marking method of Embodiment 3, it becomes possible to manufacture the semiconductor device having a marking structure whose visibility is improved. Moreover, according to the method of manufacturing a semiconductor device of Embodiment 3, it becomes possible to mark a lot of information in a small marking area.

### Embodiment 4

Hereafter, a semiconductor device according to Embodiment 4 will be explained. In this regard, points which are different from those of the semiconductor device according to Embodiments 1 to 3 will be mainly explained.

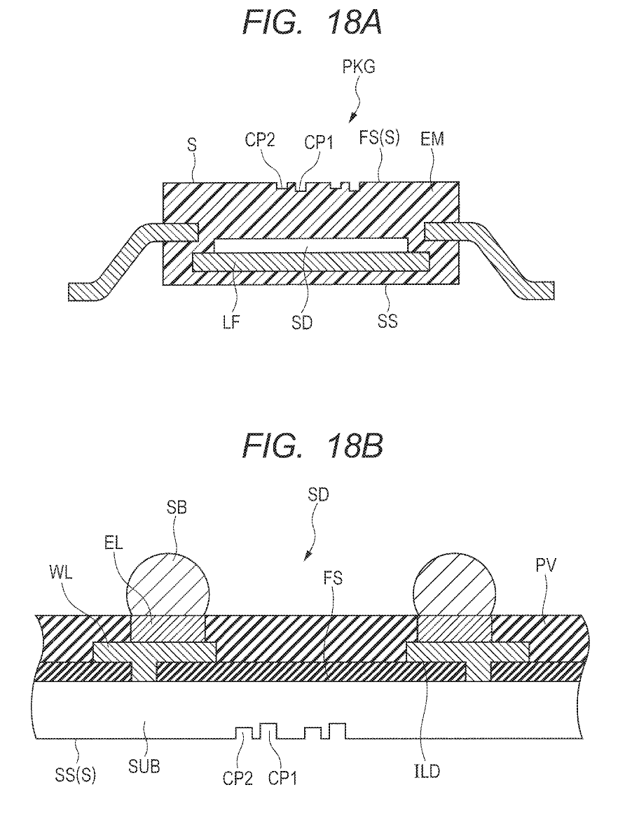

As shown in FIGS. 18A and 18B, like the semiconductor device according to Embodiments 1 to 3, a marking structure MA of the semiconductor device according to Embodiment 4 has a body for marking MB, a first concave portion CP1, and a second concave portion CP2. Moreover, as in the marking structure MA of the semiconductor device according to Embodiments 1 to 3, in the marking structure MA of the semiconductor device according to Embodiment 4, the first concave portion CP1 and the second concave portion CP2 are different in shape so that they may cause light reflection differently.

In the marking structure of the semiconductor device according to Embodiment 4, for example, as in the marking structure of the semiconductor device according to Embodiment 1, a depth D1 of the first concave portion CP1 and a depth D2 of the second concave portion CP2 are different.

In the marking structure MA of the semiconductor device according to Embodiment 4, as in the marking structure MA of the semiconductor device according to Embodiment 2, surface roughness of the bottom of the first concave portion CP1 and surface roughness of the bottom of the second concave portion CP2 may be different.

In the marking structure MA of the semiconductor device according to Embodiment 4, as in the marking structure MA of the semiconductor device according to Embodiment 3, the first concave portion CP1 maybe so configured as to reflect incident light in a direction different from one in which the second concave portion CP2 does.

However, the marking structure MA of the semiconductor device according to Embodiment 4 is different from the marking structure of the semiconductor device according to Embodiments 1 to 3 in that the body for marking MB is a sealing member EM or a semiconductor substrate SUB.

The sealing member EM is, for example, an epoxy resin or the like. As shown in FIG. 18A, the sealing member EM is a part of a semiconductor package PKG as a semiconductor device. The sealing member EM has a first surface FS and a second surface SS. The second surface SS is a surface of a side facing a printed circuit board or the like over which the semiconductor package PKG is mounted. The first surface FS is a surface on the opposite side of the second surface SS. The first surface FS corresponds to the surface S. A semiconductor device SD is arranged inside the sealing member EM. Moreover, a lead frame LF, for example, is provided inside the sealing member EM. The semiconductor device SD is mounted, for example, over the lead frame LF. In the lead frame LF, a terminal is projected from the sealing member EM.

As shown in FIG. 18B, a semiconductor substrate SUB has a first surface FS and a second surface SS. The semiconductor substrate SUB is a part of the semiconductor device SD. The second surface SS is a surface on the opposite side of the first surface FS. The second surface SS corresponds to the surface S of the body for marking MB. Semiconductor elements, such as a transistor (not shown), are formed on the side of the first surface FS of the semiconductor substrate SUB. Moreover, over the first surface FS of the semiconductor substrate SUB, for example, there are formed an interlayer insulating film ILD, wiring WL, a protective film PV, an electrode EL, and solder balls SB.

Further, a method for manufacturing a semiconductor device according to Embodiment 4 is similar to the method for manufacturing a semiconductor device according to embodiments 1 to 3.

Hereafter, there will be explained a semiconductor device according to Embodiment 4 and effects of the method for manufacturing a semiconductor device according to Embodiment 4. According to the semiconductor device and the method for manufacturing the semiconductor device of Embodiment 4, when the body for marking MB is a sealing member EM of a semiconductor package PKG, even in the case of the semiconductor substrate SUB of the semiconductor device SD, a marking structure with high visibility can be obtained.

So far, embodiments of the present invention made by the inventors have been specifically explained. However, it is to be understood that the invention is not limited to the specific embodiments described above, and many widely different embodiments of the invention can be made without departing from the spirit and scope thereof.

What is claimed is:

1. A semiconductor device having a marking structure, wherein the marking structure includes:
a body for marking having a surface;
a first mark group having a first concave portion formed in the surface;
a second mark group having a second concave portion formed adjacent to the first concave portion in the surface, and
wherein the first concave portion and the second concave portion differ in shape so that they may cause light reflection differently.

2. The semiconductor device according to claim 1, wherein the first concave portion and the second concave portion are different from each other in depth.

3. The semiconductor device according to claim 1, wherein surface roughness at a bottom of the first concave portion is different from surface roughness at a bottom of the second concave portion.

4. The semiconductor device according to claim 1, wherein the first concave portion is so configured as to reflect incident light in a direction different from one in which the second concave portion does.

5. The semiconductor device according to claim 4, wherein the first concave portion and the second concave portion are different in angle of inclination in a depth direction with respect to the surface.

6. The semiconductor device according to claim 4, wherein an angle of inclination of a bottom of the first concave portion with respect to the surface is different from an angle of inclination of a bottom of the second concave portion with respect to the surface.

7. The semiconductor device according to claim 4, wherein the first mark group forms first text information and the second mark group forms second text information which is different from the first text information.

8. The semiconductor device according to claim 1, wherein the body for marking is a semiconductor wafer.

9. The semiconductor device according to claim 1, wherein the body for marking is a semiconductor substrate.

10. The semiconductor device according to claim 1, wherein the body for marking is a sealing member in which semiconductor elements are arranged.

11. A method for manufacturing a semiconductor device having a marking structure, comprising the steps of:
forming a first concave portion in a surface of a marking body; and
forming a second concave portion adjacent to the first concave portion in the surface,
wherein the first concave portion and the second concave portion differ in shape so that they may cause light reflection differently.

12. The method for manufacturing a semiconductor device according to claim 11, wherein the first concave portion and the second concave portion are formed by applying laser to the surface of the body for marking.

13. The method for manufacturing a semiconductor device according to claim 12,
wherein the first concave portion is formed by applying laser with a first intensity, and
wherein the second concave portion is formed by applying laser with a second intensity which id different from the first intensity.

14. The method for manufacturing a semiconductor device according to claim 12,
wherein the first concave portion is formed by applying laser at a first angle with respect to the surface, and
wherein the second concave portion is formed by applying laser at a second angle being different from the first angle with respect to the surface.

15. The method for manufacturing a semiconductor device according to claim 11, wherein the body for marking is a semiconductor wafer.

16. The method for manufacturing a semiconductor device according to claim 11, wherein the body for marking is a semiconductor substrate.

17. The method for manufacturing a semiconductor device according to claim 11, wherein the body for marking is a sealing member in which semiconductor elements are arranged.
